(19) United States
(12) Patent Application Publication
(10) Pub. No.: US 2010/0238077 A1
(43) Pub. Date: Sep. 23, 2010

(54) System and Method for Receiving Antenna Measuring Signal and System for Measuring Antenna

(75) Inventors: In Kui Cho, Daejeon (KR); Je Hoon Yun, Daejeon (KR); Soon-Soo Oh, Daejeon (KR); Jung Ick Moon, MOON (KR); Joung Myoun Kim, Daejeon (KR); Soon Ik Jeon, Daejeon (KR); Chang-Joo Kim, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/681,816

(22) PCT Filed: Oct. 1, 2008
(86) PCT No.: PCT/KR2008/005797

§ 371 Date: Apr. 6, 2010

(30) Foreign Application Priority Data
Oct. 10, 2007 (KR) 10-2007-0102122

(51) Int. Cl. G01R 29/08

(52) U.S. Cl. 343/703

(57) ABSTRACT

The present invention relates to an apparatus and method for receiving an antenna measuring signal, and a system of measuring an antenna. In particular, the present invention relates to an apparatus and method for receiving an antenna measuring signal that can remove a measurement error caused by motion of an antenna cable, and a system for measuring an antenna. According to the apparatus and method for receiving an antenna measuring signal and the system and method for measuring an antenna according to the present invention, it is possible to remove a coupling effect of an RF cable of a receiving antenna side while measuring antenna characteristics, thereby minimizing a measurement error of the antenna.

### TECHNICAL FIELD

The present invention relates to an apparatus and method for receiving an antenna measuring signal, and a system for measuring an antenna. Particularly, the present invention relates to an apparatus and method for receiving an antenna measuring signal that can remove a measurement error caused by motion of an antenna cable, and a system for measuring an antenna.

This work was supported by the IT R&D program of MIC/IITA [2007-P-010-38, Development of Broadband RF Antenna Measuring Technology Standard].

### BACKGROUND ART

An antenna that is an essential element of wireless communication has been widely used in every field ranging from all kinds of enhanced technologies using radio waves such as mobile communication, radar, electronic countermeasures (ECM)/electronic counter-countermeasures (ECCM), telemetry, remote searching, electromagnetic interference (EMI)/electromagnetic compatibility (EMC) measurement, broadcasting, radio astronomy, navigation, etc., to general daily life purposes.

The antenna is classified into a transmitting antenna and a receiving antenna according to its usage. The transmitting antenna effectively radiates an electrical wave having desired characteristics in a desired direction, using an electrical signal that is supplied to the antenna. The receiving antenna is designed and manufactured to effectively receive an electrical wave that has desired characteristics and is transmitted from a desired direction among electrical waves being broadcast. The above antenna characteristics are generally determined based on antenna gain, radiation pattern (directivity), polarization characteristic, antenna efficiency, gain-to-noise temperature (G/T), and the like. Further, the available frequency band of electromagnetic waves is expanding to high frequency/super high frequency bands such as a millimeter wave region and the like. In addition, as there is a demand for the development and usage of antennas with high performance factors such as gain, directivity, and polarization characteristics, and high functions, the importance of accurate measurement of antenna characteristics has been increasing.

In an antenna or EMC measuring process that is performed by a traditional measurement scheme, a measuring signal level is affected significantly or insignificantly by the motion of a cable (radio frequency (RF) cable) of a receiving antenna. Such affect most significantly occurs in a cable being vertically connected to a vertical polarization antenna. For instance, some researchers have reported that a variation width of signal level according to the cable connected to the antenna is within the range of 7 dB to 10 dB.

The above problems caused by the antenna cable are attributed to the fact that current is induced on the external shielding surface of the RF cable corresponding to a coaxial cable and the induced current forms the cable into a secondary radiator to thereby affect the level of signals received at the receiving antenna.

Accordingly, various technologies have been used to minimize the affect of the RF cable in antenna measurement or EMC measurement.

For minimizing the affect of the RF cable, a scheme of using ferrite beads is most widely used. In the scheme, ferrite beads are attached to the RF cable that is connected to the receiving antenna at predetermined intervals, to thereby suppress the current from being generated in the RF cable corresponding to the coaxial cable. This scheme can effectively eliminate the cable radiation in a band of a few MHz through hundreds of MHz. However, there is a disadvantage in that the scheme does not effectively eliminate the current induced in the RF cable in the gigahertz band.

In another scheme of minimizing the effect of the RF cable, a sleeve-type balloon for ¼ wavelength is installed to the RF cable. However, the above scheme also has a disadvantage in that the scheme can be limitedly applicable only in a particular frequency band where the balloon effectively operates.

The above information disclosed in this Background section is only for enhancement of understanding of the background of the invention and therefore it may contain information that does not form the prior art that is already known in this country to a person of ordinary skill in the art.

### DISCLOSURE OF INVENTION

### Technical Problem

The present invention is conceived to solve the above-described problems, and thus an exemplary embodiment of the present invention provides an apparatus and method of receiving an antenna measuring signal that can minimize a measurement error occurring due to a radio frequency (RF) cable of a receiving antenna side, while measuring antenna characteristics, and a system for measuring an antenna.

### Technical Solution

In order to solve the above purposes, according to an embodiment of the present invention, there is provided an apparatus for receiving an antenna measuring signal, the apparatus including: a receiving antenna module receiving the antenna measuring signal in the form of a wireless frequency signal; an electrical-to-optical conversion module converting the antenna measuring signal, received at the receiving antenna module, from an electrical signal to an optical signal; an optical-to-electrical conversion module converting the antenna measuring signal, which is converted into the optical signal at the electrical-to-optical conversion module, to an electrical signal; and an optical cable connecting an output port of the electrical-to-optical conversion module to an input port of the optical-to-electrical conversion module.

According to another embodiment of the present invention, there is provided a system for measuring an antenna, the system including: a measuring signal transmitter transmitting an antenna measuring signal in the form of a wireless frequency signal via a transmitting antenna; a first measuring signal receiver receiving the antenna measuring signal to convert it to an optical signal; a second measuring signal receiver receiving the antenna measuring signal converted into the optical signal from the first measuring signal receiver, to convert it to an electrical signal; and a measuring signal analyzer receiving the antenna measuring signal converted into the electrical signal from the second measuring signal receiver, to analyze the received antenna measuring signal.

According to still another embodiment of the present invention, there is provided a method of receiving an antenna measuring signal, the method including: a measuring signal reception operation of receiving the antenna measuring signal in the form of a wireless frequency signal via a receiving antenna in a first space; an electrical-to-optical conversion operation of converting the antenna measuring signal to an optical signal via an electrical-to-optical conversion module; a measuring signal transmission operation of transmitting the antenna measuring signal, which is converted into the optical signal, via an optical cable to a second space corresponding to outside of the first space; and an optical-to-electrical conversion operation of converting the antenna measuring signal to an electrical signal via an optical-to-electrical conversion module in the second space.

### ADVANTAGEOUS EFFECTS

When using an apparatus and method for receiving an antenna measuring signal, and a system and method for measuring an antenna according to exemplary embodiments of the present invention, it is possible to remove the coupling effect of an RF cable of a receiving antenna side while measuring antenna characteristics, thereby minimizing a measurement error of the antenna.

### BRIEF DESCRIPTION OF THE DRAWINGS

FIG. 1 is a block diagram illustrating the configuration of a system for measuring an antenna according to an exemplary embodiment of the present invention;

FIG. 2 is a diagram illustrating a configuration of installing an antenna measuring system in an anechoic chamber according to an exemplary embodiment of the present invention;

FIG. 3 is a diagram illustrating the configuration of a system for measuring a second transfer function for correcting an antenna measuring system according to an exemplary embodiment of the present invention;

FIG. 4 is a diagram illustrating an apparatus for receiving an antenna measuring signal according to the related art;

FIG. 5 is a diagram illustrating an apparatus for receiving an antenna measuring signal according to another exemplary embodiment of the present invention;

FIG. 6 is a diagram illustrating an electrical-to-optical converter of an apparatus for receiving an antenna measuring signal in detail according to still another exemplary embodiment of the present invention;

FIG. 7 is a diagram illustrating an optical-to-electrical converter of an apparatus for receiving an antenna measuring signal in detail according to yet another exemplary embodiment of the present invention; and

FIG. 8 is a flowchart illustrating a method of receiving an antenna measuring signal according to another exemplary embodiment of the present invention.

### BEST MODE FOR CARRYING OUT THE INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout this specification and the claims that follow, when it is described that an element is “coupled” to another element, the element may be “directly coupled” to the other element or “electrically coupled” to the other element through a third element.

In the specification, unless explicitly described to the contrary, the word “comprise” and variations such as “comprises” or “comprising” will be understood to imply the inclusion of stated elements but not the exclusion of any other elements. In addition, the terms “-er”, “-or” and “module” described in the specification mean units for processing at least one function and operation and can be implemented by hardware components or software components and combinations thereof.

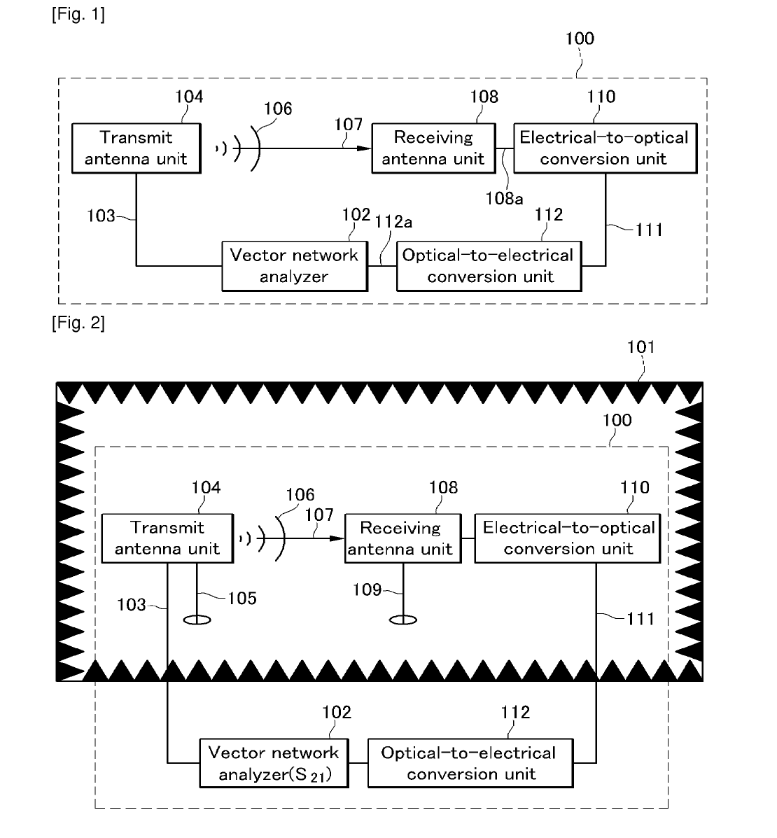

FIG. 1 is a block diagram illustrating the configuration of a system for measuring an antenna according to an exemplary embodiment of the present invention.

As shown in FIG. 1, the antenna measuring system 100 includes a transmitting antenna unit 104, a receiving antenna unit 108, an electrical-to-optical converter 110, an optical cable 111, an optical-to-electrical converter 112, and a vector network analyzer 102.

The transmitting antenna unit 104 is connected to an output port of the vector network analyzer 102 via a transmission cable 103. The transmission cable 103 is a coaxial cable.

The receiving antenna unit 108 is connected to the electrical-to-optical converter 110 via a first reception cable 108a. The electrical-to-optical converter 110 is connected to the optical-to-electrical converter 112 via the optical cable 111, and the optical-to-electrical converter 112 is connected to an input port of the vector network analyzer 102 via a second reception cable 112a.

FIG. 2 is a diagram illustrating the configuration of installing an antenna measuring system in an anechoic chamber according to an exemplary embodiment of the present invention.

Like reference numerals shown in FIG. 1 refer to the like constituent elements.

Hereinafter, a general operational principle of an antenna measuring system according to an exemplary embodiment of the present invention will be described with reference to FIG. 2.

First, a measuring signal with a predetermined frequency bandwidth and output current is output from an output port of a vector network analyzer 102. The measuring signal output from the output port of the vector network analyzer 102 is transmitted to the inside of an anechoic chamber 101 via a coaxial cable 103 and is then input to a transmitting antenna unit 104. The transmitting antenna unit 104 may be constructed to be supported by a transmitting antenna support 105.

The input measuring signal is converted into a radiation signal 106 or 107 in a radio frequency (RF) form and is then radiated in the anechoic chamber 101.

When the radiation signal 107 is received at the receiving antenna unit 108, the received radiation signal 107 is again converted into an electrical signal. The receiving antenna unit 108 may be constructed to be supported by a receiving antenna support 109.

When the measuring signal is converted into the electrical signal at the receiving antenna unit 108 and transmitted to the electrical-to-optical converter 110 connected to the receiving antenna unit 108, the measuring signal is converted into an optical signal again at the electrical-to-optical converter 110. The measuring signal converted into the optical signal is transmitted, via an optical cable 111, to an optical-to-electrical converter 112 that is positioned outside the anechoic chamber 101.

The measuring signal received at the optical-to-electrical converter 112 outside the anechoic chamber 101 is converted from the optical signal into the electrical signal. When the measuring signal converted into the electrical signal is transmitted to an input port of the vector network analyzer 102, the characteristic analysis of the measuring signal is performed.

Through the above-described process, a first transfer function S21 with respect to the entire antenna measuring system according to an embodiment of the present invention is obtained.

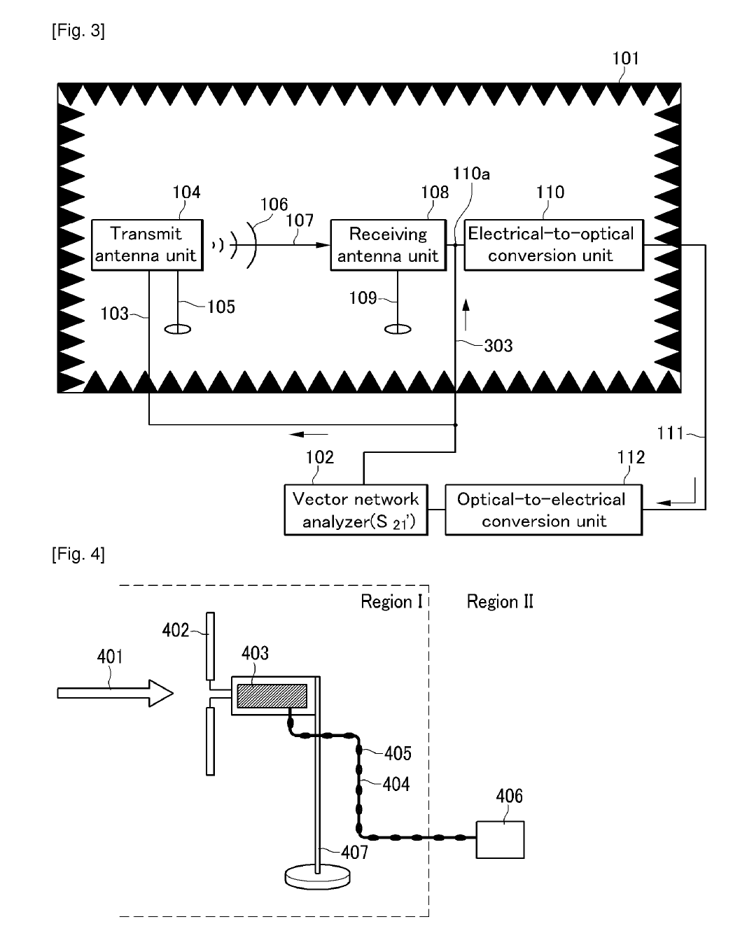

FIG. 3 is a block diagram illustrating the configuration of a system for measuring a second transfer function for correcting an antenna measuring system according to an exemplary embodiment of the present invention.

As shown in FIG. 3, in order to measure a second transfer function S21′ for correcting an antenna measuring system according to an exemplary embodiment of the present invention, a coaxial cable 303 of a minimum length is disposed between an output port of a vector network analyzer 102 and an input port 110a of an electrical-to-optical converter 110. The coaxial cable 303 of the minimum length connects the output port of the vector network analyzer 102 with the input port 110a of the electrical-to-optical converter 110 at a minimum distance.

The measuring signal output from the output port of the vector network analyzer 102 is input to the electrical-to-optical converter 110 via the minimum length coaxial cable 303 and the input port 110a

The input measuring signal is converted into an optical signal at the electrical-to-optical converter 110 and is then transmitted to an optical-to-electrical converter 112 via an optical cable 111.

Next, the measuring signal is reconverted from the optical signal to the electrical signal at the optical-to-electrical converter 112 and is then input to an input port of the vector network analyzer 102, enabling the analysis of the signal characteristic.

Through the above-described process, a second transfer function S21′ by an optical link corresponding to a system transfer function is obtained, in which the important factor is that the second transfer function by the optical link has a constant value over time.

FIG. 4 is a diagram illustrating an apparatus for receiving an antenna measuring signal according to the related art.

Referring to the corresponding relationship between constituent elements of an antenna measuring system according to an exemplary embodiment of the present invention and constituent elements of an antenna measuring signal receiving apparatus according to the related art, a radiation signal 401 of FIG. 4 corresponds to the radiation signal, i.e., the measuring signal 107, of FIG. 1, a receiving dipole antenna 402 and a balloon 403 correspond to the receiving antenna unit 108, a coaxial cable 404 corresponds to the optical cable 111, and a digital voltmeter 406 corresponds to the vector network analyzer 102. The receiving dipole antenna 402 and the balloon 403 may be supported by an antenna support 407.

Hereinafter, system operation will be described.

Initially, the measuring signal 401 radiated from a transmitting antenna is received at the receiving dipole antenna 402. The received measuring signal 401 is transmitted from an anechoic chamber (region I) to the outside (region II) thereof via the balloon 403 and along the coaxial cable 404, and is then is input to the digital voltmeter 406.

In the meantime, in the case of an antenna measuring signal receiving apparatus according the related art, current is induced at the external shielding surface of the coaxial cable 404. The induced current forms the coaxial cable 404 into a secondary radiator to thereby affect the measurement results of the measuring signal by the digital voltmeter 406.

Accordingly, in order to solve the above problems, the antenna measuring signal receiving apparatus according to the related art installs ferrite beads 405 on the external surface of the coaxial cable 404. The ferrite beads 405 are disposed on the external surface of the coaxial cable 404 at predetermined intervals, for example every 15 cm, which is very effective in reducing the current induced in the cable.

However, the reduction effect of the induced current by the ferrite beads 405 may be significantly effective only in the band of a few MHz through hundreds of MHz. Specifically, the reduction effect of the induced current may be insignificant in the gigahertz frequency band.

Also, when a sleeve-type balloon 403 for ¼ wavelength is installed, the induced current of the coaxial cable 404 may be effectively reduced, but even in this case, there is a disadvantage in that it is effective only in a particular frequency band with a limited bandwidth.

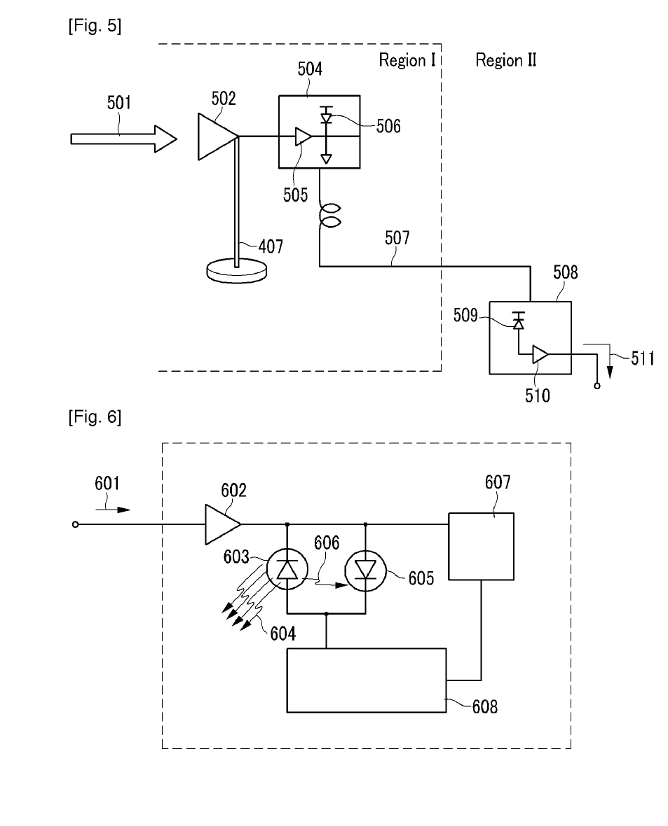

FIG. 5 is a diagram illustrating an apparatus for receiving an antenna measuring signal according to another exemplary embodiment of the present invention.

Referring to the corresponding relationship between the constituent elements of the antenna measuring system according to the related art shown in FIG. 4 and constituent elements of the antenna measuring signal receiving apparatus according to the present exemplary embodiment shown in FIG. 5, the radiation signal 401 of FIG. 4 corresponds to a radiation signal, i.e., a measuring signal 501, of FIG. 5, the receiving dipole antenna 402 and the balloon 403 correspond to a receiving antenna unit 502, and the coaxial cable 404 corresponds to an optical cable 507.

As shown in FIG. 5, in the antenna measuring system according to the present exemplary embodiment, the receiving antenna unit 502 receives the measuring signal 501 from a transmitting antenna unit (not shown). In this instance, the type of receiving antenna constituting the receiving antenna unit 502 is determined based on a frequency of the measuring signal 501. For example, when the frequency band of the measuring signal 501 is less than 1 GHz, a ½ wavelength standard dipole antenna is applied. Also, when the frequency band of the measuring signal 501 is within the range of 1 GHz to 4 GHz, a horn antenna is applied.

The measuring signal 501 received at the receiving antenna unit 502 is input to an input port of an electrical-to-optical converter 504. As shown in FIG. 5, the electrical-to-optical converter 504 further includes a low noise amplifier 505 in order to stabilize the electrical power of an input RF signal and to perform impedance matching between the receiving antenna and an electrical-to-optical conversion element 506.

The measuring signal passing through the low noise filter 505 is synthesized with an optical signal and is modulated via the electrical-to-optical conversion element 506. The modulated measuring signal is transmitted from an anechoic chamber region I to an outside region II thereof via the optical cable 507.

The measuring signal that is modulated to the optical signal is demodulated again from the optical signal to the electrical signal by an optical-to-electrical conversion element 509 of an optical-to-electrical converter 508. In this instance, the measuring signal after modulation should be modulated to have the same frequency and magnitude as the measuring signal before optical modulation.

Next, the demodulated measuring signal is amplified via an amplifier 510 to an amplified signal 511.

Through this, a reception process of the antenna measuring signal is completed.

FIG. 6 is a diagram illustrating an electrical-to-optical converter of an apparatus for receiving an antenna measuring signal in detail according to still another exemplary embodiment of the present invention.

As shown in FIG. 6, an electrical-to-optical converter of an antenna measuring system according to an exemplary embodiment of the present invention includes a low noise amplifier 602, an electrical-to-optical conversion element 603, an electrical-to-optical conversion element driving circuit 607, an optical detector 605, and a power unit 608.

First, impedance matching is performed for a measuring signal 601 received at a receiving antenna unit (not shown) via the low noise amplifier 602. Next, the measuring signal 601 is modulated to an optical signal 604 via the electrical-to-optical conversion element 603 and is then emitted to the outside of the electrical-to-optical conversion element 603.

Most measuring signals converted into the optical signals 604 are transmitted to an optical-to-electrical conversion element (not shown) via an optical cable (not shown). In this instance, only a portion of optical signals 606 are input to the optical detector 605, enabling the optical detector 605 to detect emission of optical signals 604 and 606.

When the optical detector 605 detects the optical signal 606, the optical detector 605 feeds back the detected signal 606 to the electrical-to-optical conversion element driving circuit 607, enabling the electrical-to-optical conversion element driving circuit 607 to perform the stabilized electrical-to-optical converting process.

In the meantime, in addition to the optical detector 605, the electrical-to-optical conversion element driving circuit 607 may further include a temperature compensation circuit (not shown) or an automatic power control circuit (APC) (not shown) in order to perform the stabilized electrical-to-optical converting process.

The electrical-to-optical conversion element 603 applies a type of conversion element that can directly perform modulation without needing an external modulator. This is advantageous in that it significantly reduces the manufacturing cost of the module. For example, a vertical cavity surface emitting laser diode (VCSEL) or a distributed feedback laser diode (DFLD) enabling direct modulation may be applicable for the electrical-to-optical conversion element 603.

The power unit 608 provides portable direct current (DC) power with a capacity that enables long-lasting driving of the electrical-to-optical converter. To satisfy the condition of long-lasting capacity, a general dry cell may be applicable to the power unit 608 for portability of the antenna measuring system according to the present invention.

When applying the portable DC power such as a dry cell to an antenna measuring signal receiving apparatus according to the present invention, it is possible to prevent a measurement error from occurring due to a power cable, which is different from the antenna measuring signal receiving apparatus applying the external power via the power cable according to the related art.

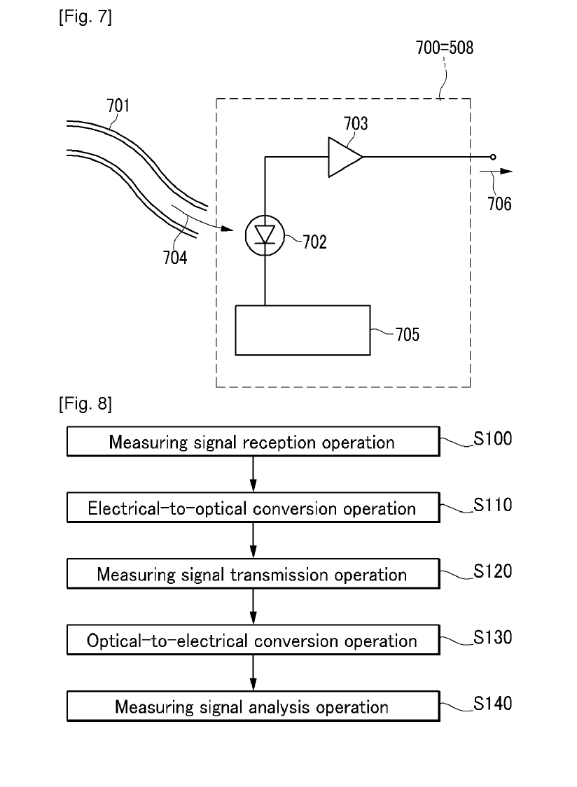

FIG. 7 is a diagram illustrating an optical-to-electrical converter of an apparatus for receiving an antenna measuring signal in detail according to yet another exemplary embodiment of the present invention.

A measuring signal converted into an optical signal 704 is input to an optical-to-electrical conversion element 702 of an optical-to-electrical converter 700 via an optical cable 701. In this instance, the optical-to-electrical conversion element 702 connected to a power unit 705 demodulates the measuring signal from the optical signal 704 to an electrical signal and then outputs the demodulated measuring signal to an impedance matching circuit 703. The impedance matching circuit 703 outputs an impedance-matched signal 706 and may be embodied using a simple amplifier.

A single-mode optical fiber may be adopted for the optical cable 701. Particularly, it is preferable that an antenna measuring system according to an exemplary embodiment of the present invention may use a polarization maintaining fiber (PMF) in order to maintain the phase of a measuring signal.

FIG. 8 is a flowchart illustrating a method of receiving an antenna measuring signal according to another exemplary embodiment of the present invention.

As shown in FIG. 8, the antenna measuring method includes a measuring signal reception operation S100, an electrical-to-optical conversion operation S110, a measuring signal transmission operation S120, an optical-to-electrical conversion operation S130, and a measuring signal analysis operation S140.

In the measuring signal reception operation S100, a measuring signal transmitted from a transmitting antenna unit of an antenna measuring system is received at a receiving antenna unit.

In the electrical-to-optical conversion operation S110, the received measuring signal is input to an electrical-to-optical converter and is then converted into an optical signal via an electrical-to-optical conversion element.

In the measuring signal transmission operation S120, when the measuring signal that is converted into the optical signal is emitted from the electrical-to-optical conversion element, the measuring signal is transmitted from the electrical-to-optical conversion element of the electrical-to-optical converter to an optical-to-electrical conversion element of an optical-to-electrical converter.

The optical cable connects the electrical-to-optical converter, disposed inside an anechoic chamber, to the optical-to-electrical converter disposed outside the anechoic chamber. Therefore, in operation S120, the measuring signal in the form of the optical signal is transferred from the inside of the anechoic chamber to the outside thereof.

In the optical-to-electrical conversion operation S130, the measuring signal in the form of the optical signal is converted into an electrical signal via the optical-to-electrical conversion element of the optical-to-electrical converter and passes through an impedance matching circuit. Through this, the measuring signal is demodulated to have an appropriate magnitude and impedance.

In the measuring signal analysis operation S140, when the reception of the antenna measuring signal is completed through the above-described process, the demodulated measuring signal of the optical-to-electrical conversion operation S130 is input to a measuring signal analyzer to be analyzed thereby.

The measuring signal analyzer may be an analyzer such as a digital voltmeter, a spectrum analyzer, and the like, which is appropriate for analyzing a measuring signal received at a receiving antenna unit and then transmitted therefrom.

As described above, an antenna measuring system and method according to an exemplary embodiment of the present invention may be very advantageous when measuring an antenna by applying a substitution scheme. Further, when a measurement target is particularly an electrical field or a magnetic field, the antenna measuring system and method may exhibit further improved performance, compared with the related art.

The above-mentioned exemplary embodiments of the present invention are not embodied only by a method and apparatus. Alternatively, the above-mentioned exemplary embodiments may be embodied by a program performing functions, which correspond to the configuration of the exemplary embodiments of the present invention, or a recording medium on which the program is recorded. These embodiments can be easily devised from the description of the above-mentioned exemplary embodiments by those skilled in the art to which the present invention pertains.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. An apparatus for receiving an antenna measuring signal, the apparatus comprising:
a receiving antenna module receiving the antenna measuring signal in the form of a wireless frequency signal;
an electrical-to-optical conversion module converting the antenna measuring signal, which is received at the receiving antenna module, into an optical signal;
an optical-to-electrical conversion module converting the antenna measuring signal, which is converted into the optical signal at the electrical-to-optical conversion module, into an electrical signal; and
an optical cable connecting an output port of the electrical-to-optical conversion module to an input port of the optical-to-electrical conversion module.

2. The apparatus of claim 1, wherein the electrical-to-optical conversion module further comprises a first impedance matching module performing impedance matching between an output port of the receiving antenna module and an input port of the electrical-to-optical conversion module.

3. The apparatus of claim 2, wherein the optical-to-electrical conversion module further comprises a second impedance matching module performing impedance matching between the output port of the electrical-to-optical matching module and an input port of an antenna measuring signal analyzing apparatus connected to the electrical-to-optical matching module.

4. The apparatus of claim 3, wherein the optical cable is a polarization maintaining fiber (PMF).

5. The apparatus of claim 4, further comprising a dry cell supplying power to the electrical-to-optical conversion module and the optical-to-electrical conversion module as portable direct current (DC) power.

6. A system for measuring an antenna, the system comprising:
a measuring signal transmitter transmitting an antenna measuring signal in the form of a wireless frequency signal via a transmitting antenna;
a first measuring signal receiver receiving the antenna measuring signal and then converting the received antenna measuring signal into an optical signal;
a second measuring signal receiver receiving the antenna measuring signal converted into the optical signal from the first measuring signal receiver, and
then converting the received antenna measuring signal into an electrical signal; and
a measuring signal analyzer receiving the antenna measuring signal converted into the electrical signal from the second measuring signal receiver, and then analyzing the received antenna measuring signal.

7. The system of claim 6, wherein the first measuring signal receiver includes:
a receiving antenna module receiving the antenna measuring signal; and
an electrical-to-optical conversion module converting the antenna measuring signal, which is received at the receiving antenna module, into the optical signal.

8. The system of claim 7, wherein the second measuring signal receiver includes:
an optical-to-electrical conversion module converting the antenna measuring signal, which is converted into the optical signal at the electrical-to-optical conversion module, into the electrical signal; and
an optical cable connecting an output port of the electrical-to-optical conversion module with an input port of the optical-to-electrical conversion module.

9. The system of claim 8, wherein the electrical-to-optical conversion module further comprises a third impedance matching module performing impedance matching between an output port of the receiving antenna module and an input port of the electrical-to-optical conversion module, and a fourth impedance matching module performing impedance matching between the output port of the electrical-to-optical conversion module and an input port of the measuring signal analyzer.

10. A method of receiving an antenna measuring signal, the method comprising:
a measuring signal reception operation of receiving the antenna measuring signal in the form of a wireless frequency signal via a receiving antenna in a first space;
an electrical-to-optical conversion operation of converting the antenna measuring signal to an optical signal via an electrical-to-optical conversion module;
a measuring signal transmission operation of transmitting the antenna measuring signal, which is converted into the optical signal, via an optical cable to a second space corresponding to outside of the first space; and
an optical-to-electrical conversion operation of converting the antenna measuring signal into an electrical signal via an optical-to-electrical conversion module in the second space.
